(19) United States
(12) Patent Application Publication
(10) Pub. No.: US 2026/0032891 A1
(43) Pub. Date: Jan. 29, 2026

(54) SEMICONDUCTOR MEMORY DEVICE AND MANUFACTURING METHOD THEREOF

(71) Applicant: Samsung Electronics Co., Ltd., Suwon-si (KR)

(72) Inventors: Taehyuk Kim, Suwon-si (KR); Taekyong Kim, Suwon-si (KR); Taejin Park, Suwon-si (KR); Hyeonkyu Lee, Suwon-si (KR)

(21) Appl. No.: 19/024,628

(22) Filed: Jan. 16, 2025

(30) Foreign Application Priority Data
Jul. 23, 2024 (KR) 10-2024-0097513

(51) Int. Cl. H10B 12/00

(52) U.S. Cl. CPC H10B 12/488; H10B 12/03; H10B 12/315; H10B 12/482

(57) ABSTRACT

A method of manufacturing a semiconductor memory device includes providing a substrate structure and forming, by etching portions of the substrate structure, a channel region and a plurality of word lines spaced apart from each other in a first direction and extending in a second direction, forming a conductive layer structure on the channel region, forming a first mask structure on the conductive layer structure, forming a plurality of first space insulating patterns, forming a second mask structure on the plurality of first space insulating patterns, forming a plurality of second space insulating patterns, forming a plurality of first insulating patterns by removing portions of the plurality of first space insulating patterns using the plurality of second space insulating patterns as a first etch mask, and forming a plurality of contact plugs using the plurality of first insulating patterns as a second etch mask.

### CROSS-REFERENCE TO RELATED APPLICATION

This application is based on and claims priority under 35 U.S.C. § 119 to Korean Patent Application No. 10-2024-0097513, filed on Jul. 23, 2024, in the Korean Intellectual Property Office, the disclosure of which is incorporated by reference herein in its entirety.

### TECHNICAL FIELD

The inventive concept relates to a semiconductor memory device and a manufacturing method thereof.

### BACKGROUND

A semiconductor memory device may include a vertical channel transistor and a method of manufacturing the semiconductor memory device.

Demand for down-scaling of integrated circuit devices, makes it necessary to ensure operational accuracy as well as a fast operation speed in semiconductor memory devices. Accordingly, research has been conducted to optimize performance and increase reliability of semiconductor memory devices.

### SUMMARY

According to an aspect of the inventive concept, there is provided a semiconductor memory device. The semiconductor memory device may include a lower contact plug and an upper contact plug which may be formed in an integrated structure.

The inventive concept provides a method of manufacturing a semiconductor memory device which may include a lower contact plug and an upper contact plug formed in an integrated structure.

The technical objectives to be achieved by the inventive concept are not limited to the above-described objectives and intend to encompass other technical objectives that are not mentioned herein but would be clearly understood by a person skilled in the art from the description of the disclosure.

According to an aspect of the inventive concept, there is provided a method of manufacturing a semiconductor memory device, the method including providing a substrate structure including a substrate, an embedded insulating layer, and an active layer, sequentially stacked. A channel region and a plurality of word lines may be formed by etching portions of the substrate structure. The channel region and the plurality of word lines may be spaced apart from each other in a first direction and may extend in a second direction that intersects the first direction. The method may include forming a conductive layer structure on the channel region, forming a first mask structure on the conductive layer structure, forming a plurality of first space insulating patterns by etching portions of the first mask structure, forming a second mask structure on the plurality of first space insulating patterns, forming a plurality of second space insulating patterns by etching portions of the second mask structure, forming a plurality of first insulating patterns by removing portions of the plurality of first space insulating patterns using the plurality of second space insulating patterns as a first etch mask, and forming a plurality of contact plugs by etching portions of the conductive layer structure using the plurality of first insulating patterns as a second etch mask.

According to an aspect of the inventive concept, there is provided a method of manufacturing a semiconductor memory device, the method including providing a substrate structure including a substrate, an embedded insulating layer, and an active layer, sequentially stacked. Forming, by etching portions of the substrate structure, a channel region and a plurality of word lines spaced apart from each other in a first direction and extending in a second direction that intersects the first direction, forming a conductive layer structure and an insulating layer that are sequentially on the channel region, forming a first mask structure on the insulating layer, forming, by etching portions of the first mask structure, a plurality of first space insulating patterns that extend in the second direction, forming a second mask structure on the plurality of first space insulating patterns, forming, by etching portions of the second mask structure, a plurality of second space insulating patterns that extend in the first direction, forming a plurality of first insulating patterns by removing portions of the plurality of first space insulating patterns using the plurality of second space insulating patterns as a first etch mask, forming a plurality of second insulating patterns on the conductive layer structure by patterning the insulating layer using the plurality of first insulating patterns as a second etch mask, and forming a plurality of contact plugs in an integrated structure including an upper contact plug and a lower contact plug, by etching portions of the conductive layer structure using the plurality of second insulating patterns as a third etch mask

According to an aspect of the inventive concept, there is provided a semiconductor memory device including a plurality of conductive lines extending in a first direction, a plurality of channel regions connected to the plurality of conductive lines, a pair of word lines between a first channel region and an adjacent second channel region of the plurality of channel regions, spaced apart from each other in the first direction, and extending in a second direction that intersects the first direction, and a plurality of contact plugs spaced apart from the plurality of conductive lines with the plurality of channel regions therebetween in a third direction that is perpendicular to the first and second directions, where each of the plurality of contact plugs including a lower contact plug in contact with a channel region of the plurality of channel regions and an upper contact plug in contact with an upper surface of the lower contact plug, where the lower contact plug and the upper contact plug are an integrated structure.

### BRIEF DESCRIPTION OF THE DRAWINGS

Embodiments of the inventive concept will be more clearly understood from the following detailed description taken in conjunction with the accompanying drawings in which:

FIG. 1 is a plan diagram illustrating some components of a semiconductor memory device according to some embodiments;

FIG. 2A is a cross-sectional view of the semiconductor memory device taken along line X1-X1′ of FIG. 1;

FIG. 2B is a cross-sectional view of the semiconductor memory device taken along line Y1-Y1′ of FIG. 1;

FIG. 3 is an enlarged cross-sectional view showing the region “EX1” in FIG. 2A; and

FIGS. 4A, 4B, 5A, 5B, 6A, 6B, 7A, 7B, 8A, 8B, 9A, 9B, 10A, 10B, 11A, 11B, 12A, 12B, 13A, 13B, 14A, 14B are cross-sectional views showing a method of manufacturing a semiconductor memory device, according to some embodiments, according to a process order, in which FIGS. 4A, 5A, 6A, 7A, 8A, 9A, 10A, 11A, 12A, 13A, and 14A are cross-sectional views of the semiconductor memory device taken along line X1-X1′ of FIG. 1, while FIGS. 4B, 5B, 6B, 7B, 8B, 9B, 10B, 11B, 12B, 13B, and 14B are cross-sectional views of the semiconductor memory device taken along line Y1-Y1′ of FIG. 1, and FIGS. 7C, 9C, 10C, and 12C are plan views of the semiconductor memory device according to example embodiments.

### DETAILED DESCRIPTION

Hereinafter, example embodiments of the inventive concept will be described more fully with reference to the accompanying drawings.

The term “first,” “second,” or the like used herein may modify various elements regardless of the order and/or priority thereof, and is used only for distinguishing one element from another element, without limiting example embodiments. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” as used herein, refers to electrical and/or physical connection between elements or components and does not preclude the presence of additional elements or components therebetween. The term “cover,” “covers,” or the like used herein may specify an element that is partially or fully, on, surrounding, or encasing another element. The term “in contact with” may be used herein to specify an element or layer that is directly adjacent to another element or layer without the presence of at least one additional element or layer therebetween. Likewise, when components or layers are referred to herein as “directly” on, or “in direct contact” or “directly connected,” no intervening components or layers are present. The term “overlap,” “overlaps,” and/or “overlapping,” when used herein may specify the position of an element as on, in contact with, and/or covering another element. Components or layers described with reference to “overlap” in a particular direction may be at least partially obstructed by one another when viewed along a line extending in the particular direction or in a plane perpendicular to the particular direction.

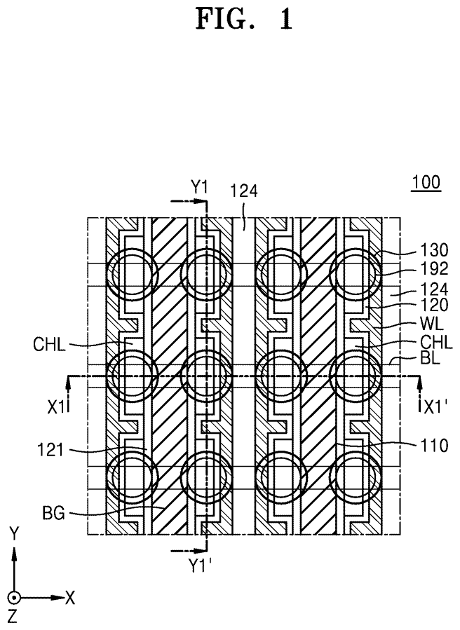

FIG. 1 is a plan diagram illustrating some components of a semiconductor memory device 100 according to some embodiments.

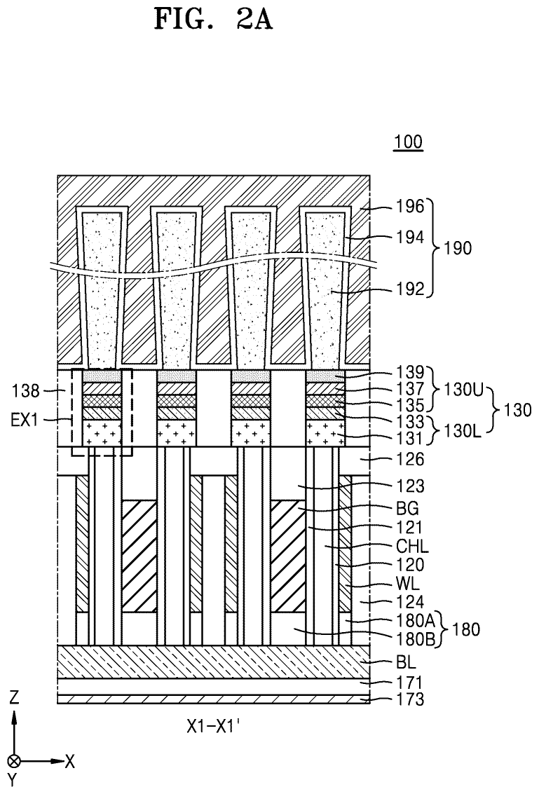

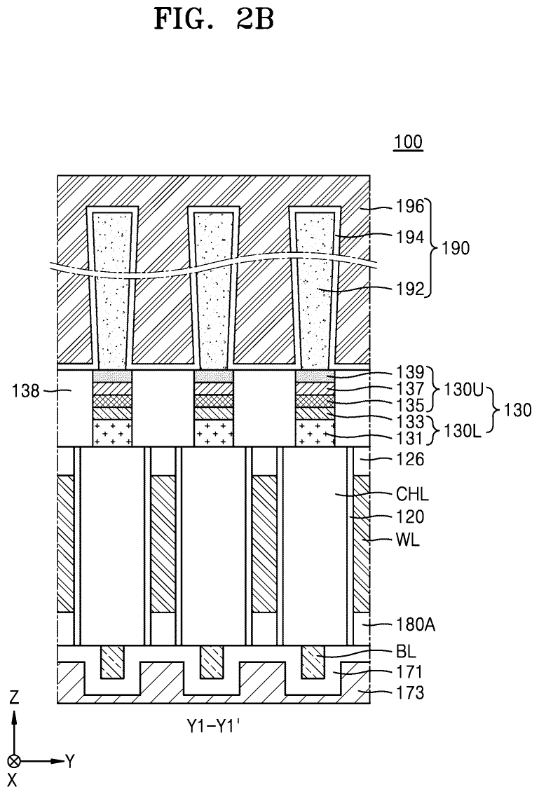

FIG. 2A is a cross-sectional view of the semiconductor memory device 100 taken along line X1-X1′ of FIG. 1.

FIG. 2B is a cross-sectional view of the semiconductor memory device 100 taken along line Y1-Y1′ of FIG. 1.

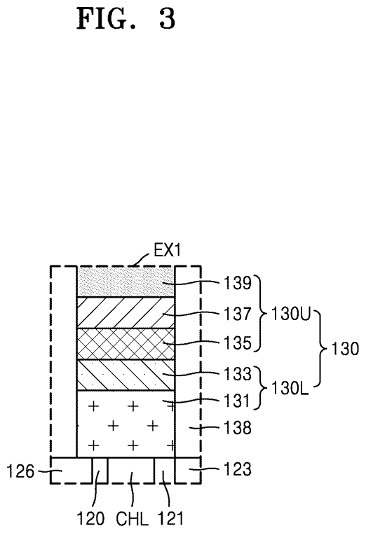

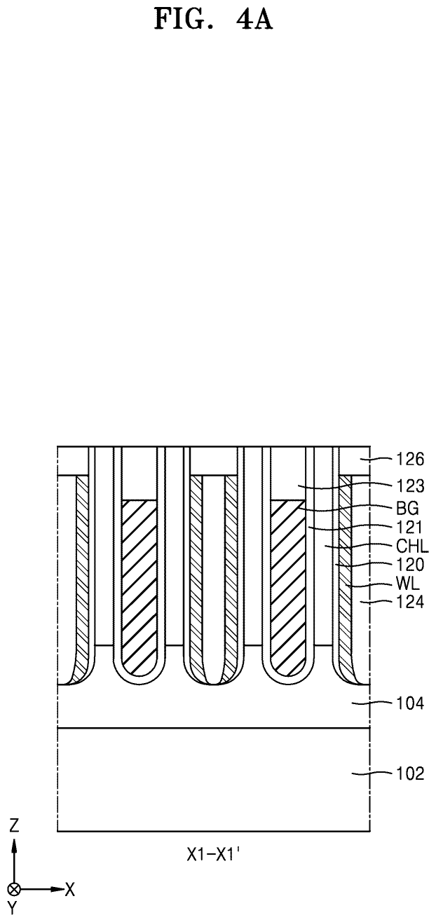

FIG. 3 is an enlarged cross-sectional view of a region “EX1” in FIG. 2A.

Referring to FIGS. 1, 2A, 2B, and 3, the semiconductor memory device 100 may include a plurality of conductive lines BLs which extend in a first horizontal direction (e.g. first direction and/or X direction) and are arranged spaced apart from each other in a second horizontal direction (e.g. second direction and/or Y direction) perpendicular to the first horizontal direction (e.g. X direction). In the semiconductor memory device 100, the plurality of conductive lines BLs may each form a bit line.

In some embodiments, each channel region of a plurality of channel regions CHLs may be on top of the plurality of conductive lines BLs, and a plurality of contact plugs 130 may be on top of the plurality of channel regions CHLs, respectively. The plurality of channel regions CHLs may be arranged between the plurality of conductive lines BLs and the plurality of contact plugs 130 to be spaced apart from each other in the first horizontal direction (e.g. X direction) and the second horizontal direction (e.g. Y direction). The plurality of channel regions CHLs may each have one end portion connected to the plurality of conductive lines BLs and the other end portion connected to a contact plug of the plurality of contact plugs 130. The plurality of channel regions CHLs may be in contact with the plurality of conductive lines BLs and the plurality of contact plugs 130, respectively.

In some embodiments, the plurality of conductive lines BLs may extend in the first horizontal direction (e.g. X direction), and a shield metal layer 173 may be disposed to fill a space between the plurality of conductive lines BLs. For example, the plurality of conductive lines BLs may extend in the first horizontal direction (e.g. X direction), and the shield metal layer 173 may fill a portion of the space between the plurality of conductive lines BLs and extend in the first horizontal direction (e.g. X direction).

In some embodiments, the side wall (i.e. side surface) and the bottom surface of the plurality of conductive lines BLs may be covered (i.e. enclosed) by a conductive line insulating layer 171. For example, the conductive line insulating layer 171 may be between the side walls of the plurality of conductive lines BLs and the shield metal layer 173, and between the bottom surfaces of the plurality of conductive lines BLs and the shield metal layer 173.

In some embodiments, the plurality of conductive lines BLs may each include metal and/or polysilicon doped with conductive metal nitride. For example, the conductive lines BLs may each include Ti, TiN, Ta, TaN, Mo, Ru, W, WN, Co, Ni, RuTiN, and/or a combination thereof. In some embodiments, the shield metal layer 173 may include Ti, TiN, Ta, TaN, Mo, Ru, W, WN, Co, Ni, Cu, Al, TiSi, TiSiN, WSi, WSiN, TaSi, TaSiN, RuTiN, CoSi, NiSi, and/or a combination thereof.

The plurality of contact plugs 130 may be separated from the plurality of conductive lines BLs in a vertical direction (e.g. third direction and/or Z direction) with the plurality of channel regions CHLs therebetween. The plurality of contact plugs 130 may be in the form of a matrix to be separated from each other in the first horizontal direction (e.g. X direction) and the second horizontal direction (e.g. Y direction). The plurality of contact plugs 130 may be respectively connected to the plurality of channel regions CHLs.

In some embodiments, the plurality of contact plugs 130 may each include a lower contact plug 130L and an upper contact plug 130U, respectively. In this state, the lower contact plug 130L may include a first lower conductive pattern 131 and a second lower conductive pattern 133. The upper contact plug 130U may include a first upper conductive pattern 135, a second upper conductive pattern 137, and a third upper conductive pattern 139.

In some embodiments, the first lower conductive pattern 131, the second lower conductive pattern 133, the first upper conductive pattern 135, the second upper conductive pattern 137, and the third upper conductive pattern 139 may be sequentially stacked in the vertical direction (e.g. Z direction). More specifically, the lower contact plug 130L may include the first lower conductive pattern 131 in contact with the plurality of channel regions CHL and the second lower conductive pattern 133 disposed on the first lower conductive pattern 131. Furthermore, the upper contact plug 130U may include the first upper conductive pattern 135 in contact with the second lower conductive pattern 133, the second upper conductive pattern 137 on the first upper conductive pattern 135, and the third upper conductive pattern 139 on the second upper conductive pattern 137 and in contact with a capacitor structure 190.

In some embodiments, a lower surface of the lower contact plug 130L may be in contact with an upper surface of a channel region of the plurality of channel regions CHL, and an upper surface of the lower contact plug 130L may be in contact with a lower surface of the upper contact plug 130U. The lower contact plug 130L may electrically and physically connect the plurality of channel regions CHL to the upper contact plug 130U. A lower surface of the first lower conductive pattern 131 may be in contact with the upper surface of the plurality of channel regions CHL, and an upper surface of the second lower conductive pattern 133 may be in contact with the lower surface of the upper contact plug 130U, but example embodiments are not limited thereto. For example, when the first lower conductive pattern 131 is omitted, a lower surface of the second lower conductive pattern 133 may be in contact with the upper surface of the plurality of channel regions CHL, and the upper surface of the second lower conductive pattern 133 may be in contact with the lower surface of the upper contact plug 130U. In example embodiments, when the second lower conductive pattern 133 is omitted, the lower surface of the first lower conductive pattern 131 may be in contact with the upper surface of the plurality of channel regions CHL, and an upper surface of the first lower conductive pattern 131 may be in contact with the lower surface of the upper contact plug 130U.

In some embodiments, the lower surface of the upper contact plug 130U may be in contact with the upper surface of the lower contact plug 130L, and an upper surface of the upper contact plug 130U may be in contact with a lower electrode of the plurality of lower electrodes 192 of the capacitor structure 190. The upper contact plug 130U may electrically and physically connect the lower contact plug 130L to the capacitor structure 190. A lower surface of the first upper conductive pattern 135 may be in contact with the upper surface of the lower contact plug 130L, and an upper surface of the third upper conductive pattern 139 may be in contact with the lower electrode 192.

In some embodiments, the plurality of contact plugs 130 may each include metal, conductive metal nitride, metal silicide, doped polysilicon, and/or a combination thereof. The plurality of contact plugs 130 may each include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, and/or a combination thereof.

For example, the first lower conductive pattern 131 may include undoped polysilicon, and the second lower conductive pattern 133 may include doped polysilicon. The first upper conductive pattern 135 may include metal silicide, and the second upper conductive pattern 137 and the third upper conductive pattern 139 may each include metal. In this state, the upper contact plug 130U may function as a landing pad in contact with the lower electrode 192 of the capacitor structure 190. The second upper conductive pattern 137 may include, as a barrier pattern, titanium, titanium nitride, and/or a combination thereof. The third upper conductive pattern 139 may include tungsten (W).

In some embodiments, the lower contact plug 130L and the upper contact plug 130U may be an integrated structure. As the lower contact plug 130L and the upper contact plug 130U are formed in the integrated structure, a side wall (i.e. side surface) of the lower contact plug 130L may be coplanar with a side wall (i.e. side surface) of the upper contact plug 130U. For example, an interface between the side wall of the lower contact plug 130L and an interlayer insulating film 138 may be coplanar with an interface between the side wall of the upper contact plug 130U and the interlayer insulating film 138. In other words, the interface between the side wall of the lower contact plug 130L and the side wall of the upper contact plug 130U with the side wall of the interlayer insulating film 138, respectively, may extend in the vertical direction and is contiguous in a first and a second direction.

In some embodiments, the width of the lower contact plug 130L may be the same as the width of the upper contact plug 130U, but example embodiments are not limited thereto. For example, the plurality of contact plugs 130 may have a tapered shape with a width gradually decreasing from top to bottom. In example embodiments, the plurality of contact plugs 130 may have a trapezoidal shape with a width gradually increasing from top to bottom.

In some embodiments, the plurality of contact plugs 130 may be separated from each other by the interlayer insulating film 138. The plurality of contact plus 130 may be located adjacent to each other in the X direction and the Y direction. The plurality of contact plugs 130 may each have various shapes such as a circular shape, an oval shape, a rectangular shape, a square shape, a rhomboid shape, a hexagonal shape, etc., in a plan view.

As illustrated in FIG. 1, the channel regions CHLs may include a first group of a plurality of channel regions CHLs in a row in the first horizontal direction (e.g. X direction) to be spaced apart from each other in the first horizontal direction (e.g. X direction), and a second group of the plurality of channel regions CHLs in a row in the second horizontal direction (e.g. Y direction) to be spaced apart from each other in the second horizontal direction (e.g. Y direction). Each of the plurality of contact plugs 130 may be on a channel region of the plurality of channel regions CHLs. Each of the contact plugs 130 may be in contact with a channel region of the plurality of channel regions CHLs by passing through the interlayer insulating film 138. The interlayer insulating film 138 may include a silicon oxide film, a silicon nitride film, and/or a combination thereof.

In some embodiments, the plurality of channel regions CHLs may each include silicon, for example, monocrystalline silicon, polycrystalline silicon, and/or amorphous silicon. In some embodiments, the plurality of channel regions CHLs may each include at least one of Ge, SiGe, SiC, GaAs, InAs, and/or InP. In some embodiments, the plurality of channel regions CHLs may each include a conductive area, for example, a well doped with impurities and/or a structure doped with impurities.

In some embodiments, a plurality of back gate electrodes BGs and a plurality of word lines WLs may be above each of the plurality of conductive lines BLs. The plurality of back gate electrodes BGs and the plurality of word lines WLs may each extend in the second horizontal direction (e.g. Y direction) between the plurality of conductive lines BLs and the plurality of contact plugs 130. The plurality of back gate electrodes BGs and the plurality of word lines WLs may each be spaced apart from each other in the first horizontal direction (e.g. X direction).

In some embodiments, a back gate electrode BG and a pair of word lines WLs are aligned in a row in the first horizontal direction (e.g. X direction) on a conductive line BL, and the back gate electrode BG, and the pair of word lines WLs are alternately arranged on the conductive line BL. Thus, the back gate electrode BG and each word line of the pair of word lines WLs may be spaced apart from each other with one channel region CHL therebetween. In other words, pairs of word lines WLs adjacent to each other may be arranged between the back gate electrodes BGs. In example embodiments, a pair of word lines WL adjacent to each other may be separated by a back gate electrode BG. The pair of word lines WL and the back gate electrode may be alternately arranged on a conductive line BL in the X direction.

In some embodiments, the plurality of back gate electrodes BGs may each include metal, conductive metal nitride, doped polysilicon, and/or a combination thereof. For example, the back gate electrodes BGs may each include Ti, TiN, Ta, TaN, Mo, Ru, W, WN, TiSiN, WSiN, doped polysilicon, and/or a combination thereof, but example embodiments are not limited thereto. The plurality of word lines WLs may each include metal, conductive metal nitride, and/or a combination thereof. For example, the plurality of word lines WLs may each include Ti, TiN, Ta, TaN, Mo, Ru, W, WN, TiSiN, WSiN, and/or a combination thereof, but example embodiments are not limited thereto.

In some embodiments, the plurality of back gate electrodes BGs may extend in the second horizontal direction (e.g. Y direction) between two channel regions CHLs adjacent to each other in the first horizontal direction (e.g. X direction). The plurality of back gate electrodes BGs may be arranged at a position apart from each of the plurality of conductive lines BLs and the plurality of contact plugs 130 in the vertical direction (e.g. Z direction).

In some embodiments, the semiconductor memory device 100 may include a plurality of back gate dielectric films 121 covering the plurality of back gate electrodes BGs. The plurality of back gate dielectric films 121 may be provided between each back gate electrode BG and channel region CHL. The plurality of back gate dielectric films 121 may each be in contact with an adjacent one of the plurality of back gate electrodes BGs and an adjacent one of the plurality of channel regions CHLs. The plurality of back gate dielectric films 121 may each have one end portion in contact with the plurality of conductive lines BLs and the other end portion in contact with the plurality of contact plugs 130.

A first capping insulating pattern 123 may be arranged between the plurality of back gate electrodes BGs and the plurality of contact plugs 130 and between a pair of channel regions CHLs adjacent to each other. A second capping insulating patterns 180B may be arranged between the plurality of back gate electrodes BGs and the plurality of conductive lines BLs and between the pair of channel regions CHLs adjacent to each other. The first capping insulating pattern 123, the back gate electrode BG, and the second capping insulating patterns 180B may be arranged to overlap one another in the vertical direction (e.g. Z direction).

In some embodiments, the first capping insulating pattern 123 and the second capping insulating patterns 180B may each include a silicon oxide film, a silicon nitride film, and/or a combination thereof. In some embodiments, the first capping insulating pattern 123 and the second capping insulating patterns 180B may include different materials. For example, the first capping insulating pattern 123 may include a silicon oxide film, and the second capping insulating patterns 180B may include a silicon nitride film. In some embodiments, the first capping insulating pattern 123 and the second capping insulating patterns 180B may include the same material. For example, the first capping insulating pattern 123 and the second capping insulating patterns 180B may include the same material selected from among a silicon oxide film and a silicon nitride film.

In some embodiments, the word lines WLs may each be arranged at a position apart from each of the conductive lines BLs and the contact plugs 130 in the vertical direction (e.g. Z direction). A pair of word lines WLs may be arranged between the back gate electrodes BGs adjacent to each other in the first horizontal direction (e.g. X direction). The pair of word lines WLs may be apart from the back gate electrodes BGs, with one channel region CHL therebetween, in the first horizontal direction (e.g. X direction).

A separation insulating pattern 124 may be arranged between the pair of word lines WLs between the pair of channel regions CHLs adjacent to each other. A first embedded insulating pattern 126 may be arranged between the pair of word lines WLs and the plurality of contact plugs 130, and a pair of second embedded insulating patterns 180A may be arranged between the pair of word lines WLs and the plurality of conductive lines BLs. The plurality of word lines WLs, the first embedded insulating pattern 126, and the second embedded insulating patterns 180A may be arranged to overlap one another in the vertical direction (e.g. Z direction) between the pair of channel regions CHLs adjacent to each other. The pair of word lines WLs may be apart from the plurality of contact plugs 130 in the vertical direction (e.g. Z direction) with the first embedded insulating pattern 126 therebetween. The plurality of word lines WLs may be apart from the plurality of conductive lines BLs with the second embedded insulating patterns 180A therebetween. The length of the second embedded insulating patterns 180A and the length of the second capping insulating patterns 180B may be the same or similar to each other in the vertical direction (e.g. Z direction). The second embedded insulating patterns 180A and the second capping insulating patterns 180B may constitute an embedded structure 180 that is in contact with the plurality of conductive lines BLs.

In some embodiments, the separation insulating pattern 124, the first embedded insulating pattern 126, and the second embedded insulating patterns 180A may each include a silicon oxide film, a silicon nitride film, and/or a combination thereof. In some embodiments, the separation insulating pattern 124, the first embedded insulating pattern 126, and the second embedded insulating patterns 180A may all include the same or similar material. In some other embodiments, at least one of the separation insulating pattern 124, the first embedded insulating pattern 126, and the second embedded insulating patterns 180A may include a different material. For example, the separation insulating pattern 124, the first embedded insulating pattern 126, and the second embedded insulating patterns 180A may each include a silicon nitride film, but example embodiments are not limited thereto.

A gate dielectric film 120 may be provided between each of the word lines WLs and the channel region CHL adjacent to the corresponding word line WL. A pair of gate dielectric films 120 may be arranged between the pair of channel regions CHLs adjacent to each other, and the pair of word lines WLs may be arranged between the pair of gate dielectric films 120. The pair of gate dielectric films 120 may each have one end portion in contact with the plurality of conductive lines BLs and the other end portion in contact with one selected from the plurality of contact plugs 130.

In some embodiments, the plurality of gate dielectric films 120 and the plurality of back gate dielectric films 121 may each include a silicon oxide film, a high-k dielectric film, and/or a combination thereof. The high-k dielectric film refers to a film having a dielectric constant greater than a silicon oxide film. In some embodiments, the plurality of gate dielectric films 120 and the plurality of back gate dielectric films 121 may each include at least one selected from among silicon oxide, hafnium oxide (HfO), hafnium silicate (HfSiO), hafnium oxide nitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxide nitride (ZrON), zirconium silicon oxide nitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate, bismuth iron oxide (BFO), strontium titanium oxide (SrTiO), yttrium oxide (YO), aluminum oxide (AlO), and/or lead scandium tantalum oxide (PbScTaO). The plurality of back gate electrodes BGs, the plurality of word lines WLs, the plurality of channel regions CHLs, the plurality of back gate dielectric films 121, and the plurality of gate dielectric films 120, which are arranged between the plurality of conductive lines BLs and the plurality of contact plugs 130 may constitute a plurality of vertical channel transistors.

The capacitor structure 190 may be disposed on the plurality of contact plugs 130 and the interlayer insulating film 138. The capacitor structure 190 may include a plurality of lower electrodes 192, a capacitor dielectric film 194 conformally covering a surface of each of the plurality of lower electrodes 192, and an upper electrode 196 covering the plurality of lower electrodes 192 with the capacitor dielectric film 194 therebetween. Each of the plurality of lower electrodes 192 may be connected to the plurality of channel regions CHL through one of the plurality of contact plugs 130.

In the semiconductor memory device 100 described with reference to FIGS. 1, 2A, 2B, and 3, as the upper contact plug 130U and the lower contact plug 130L are formed in an integrated structure through one etching process in a manufacturing process, the deterioration of the plurality of contact plugs 130 occurring in the process of forming the plurality of contact plugs 130 may be prevented. As the upper contact plug 130U is formed in an integrated structure with the lower contact plug 130L, by omitting a landing pad replacement process, a factor affecting the threshold dimension of the upper contact plug 130U may be reduced so that the semiconductor memory device 100 having a structure with improved reliability may be provided.

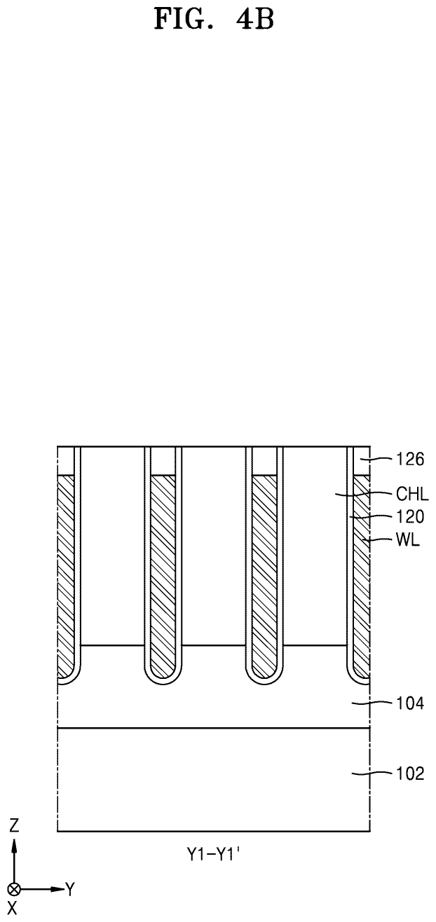

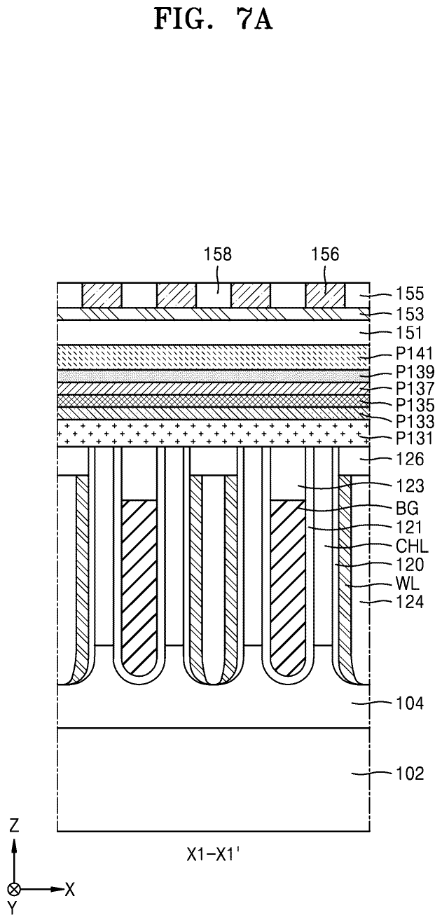

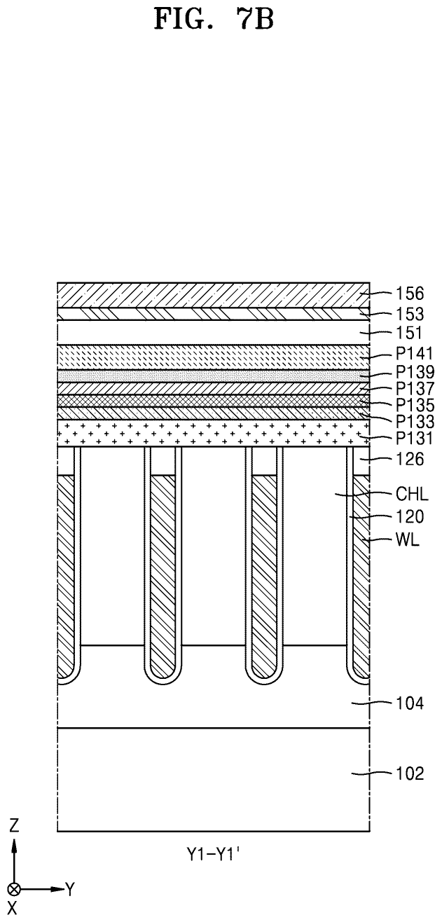

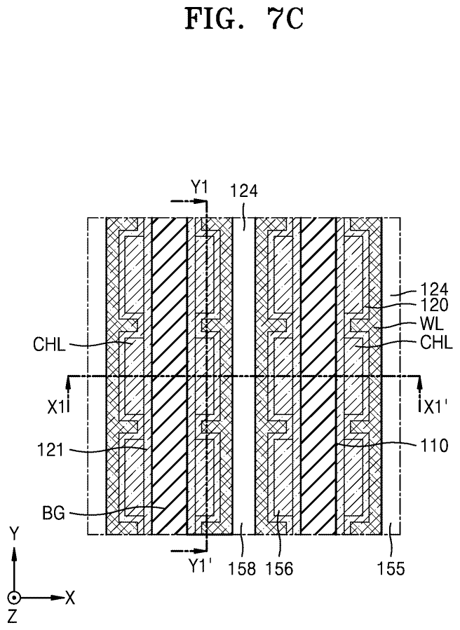

FIGS. 4A to 14B are cross-sectional views showing a method of manufacturing a semiconductor memory device, according to some embodiments, according to a process order, in which FIGS. 4A, 5A, 6A, 7A, 8A, 9A, 10A, 11A, 12A, 13A, and 14A are cross-sectional views of the semiconductor memory device taken along line X1-X1′ of FIG. 1, FIGS. 4B, 5B, 6B, 7B, 8B, 9B, 10B, 11B, 12B, 13B, and 14B are cross-sectional views of the semiconductor memory device taken along line Y1-Y1′ of FIG. 1, and FIGS. 7C, 9C, 10C, and 12C are plan views of the semiconductor memory device according to example embodiments.

Referring to FIGS. 4A and 4B, a substrate structure is prepared, in which a substrate 102, an embedded insulating layer 104, and an active layer (not shown) are sequentially stacked in the vertical direction (e.g. Z direction), a plurality of first trenches are formed by etching some areas of the substrate structure, and the plurality of back gate dielectric films 121, the plurality of back gate electrodes BGs, and the plurality of first capping insulating patterns 123 covering (i.e. on) each of the first trenches may be formed.

In this state, the substrate structure may be a silicon on insulator (SOI) substrate. The substrate 102 may be a silicon substrate. The embedded insulating layer 104 may include a silicon oxide film. The active layer may include at least one selected from among Ge, SiGe, SiC, GaAs, InAs, and/or InP. In some embodiments, the active layer may include a well doped with impurities and/or a structure doped with impurities.

Then, a plurality of second trenches are formed by etching some areas of the substrate structure, and the plurality of gate dielectric films 120, the plurality of word lines WLs, the plurality of separation insulating patterns 124, and the plurality of first embedded insulating patterns 126 may be formed covering (i.e. on) each of the second trenches. In this process, portions of the active layer of the substrate structure, which are not etched, may remain as the plurality of channel regions CHLs. Furthermore, as a planarization process is performed, the plurality of channel regions CHLs may be exposed.

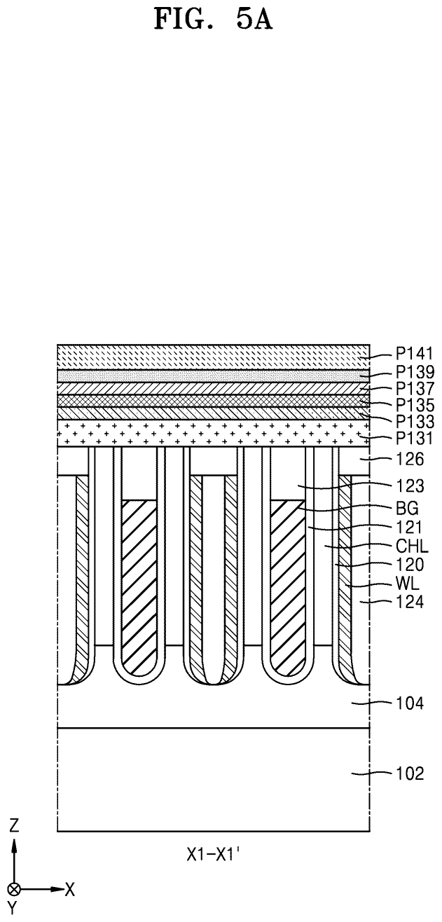

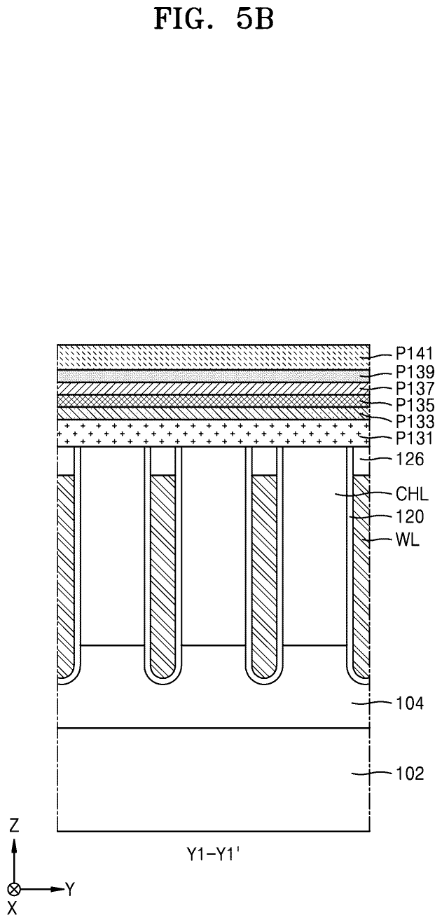

Referring to FIGS. 5A and 5B, a conductive layer structure may be formed on the result of FIGS. 4A and 4B to cover the channel regions CHLs. The conductive layer structure may include a first lower conductive layer P131, a second lower conductive layer P133, a first upper conductive layer P135, a second upper conductive layer P137, and a third upper conductive layer P139.

In some embodiments, to cover the plurality of channel regions CHLs, the first lower conductive layer P131, the second lower conductive layer P133, the first upper conductive layer P135, the second upper conductive layer P137, the third upper conductive layer P139, and a first insulating layer P141 may be sequentially stacked and formed. The first lower conductive layer P131, the second lower conductive layer P133, the first upper conductive layer P135, the second upper conductive layer P137, the third upper conductive layer P139, and the first insulating layer P141 may be formed through a chemical vapor deposition (CVD) process and a similar process of the like.

In some embodiments, the first lower conductive layer P131, the second lower conductive layer P133, the first upper conductive layer P135, the second upper conductive layer P137, and the third upper conductive layer P139 may be in the form of a flat plate. As the conductive layer structure is formed in the form of a flat plate having a large area, an area for forming a silicide layer may increase. Compared with a method of manufacturing a semiconductor memory device, according to a comparative example, the first upper conductive layer P135 may be formed in the form of a flat plate having a large area. As the first upper conductive layer P135 is formed in the form of a flat plate having a large area, a material included in the first upper conductive layer P135 may be designed through various methods.

In some embodiments, the first lower conductive layer P131, the second lower conductive layer P133, the first upper conductive layer P135, the second upper conductive layer P137, and the third upper conductive layer P139 may include the same material as the first lower conductive pattern 131, the second lower conductive pattern 133, the first upper conductive pattern 135, the second upper conductive pattern 137, and the third upper conductive pattern 139, respectively, as described above. The first insulating layer P141 may include silicon nitride, silicon oxide, silicon oxynitride, and/or a combination thereof.

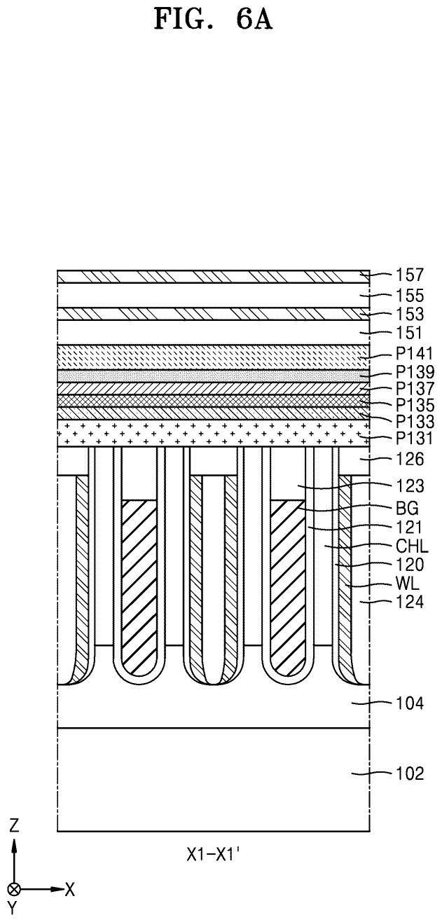

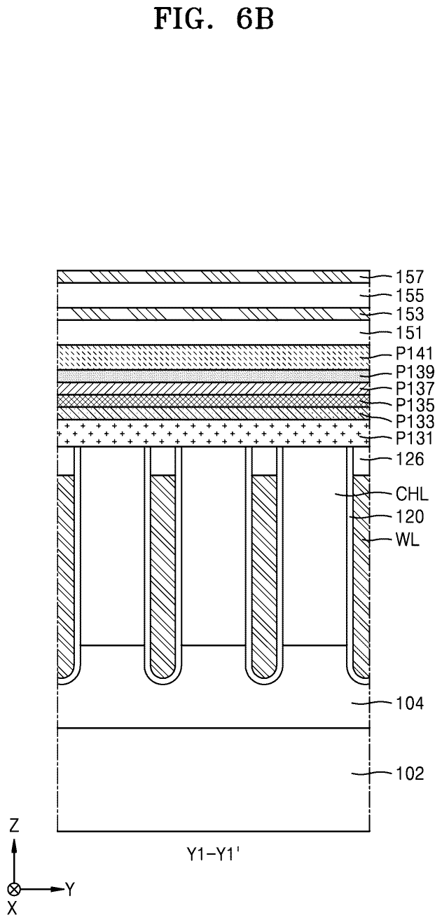

Referring to FIGS. 6A and 6B, a first mask structure may be formed on the result of FIGS. 5A and 5B to cover the first insulating layer P141. The first mask structure may include a first mask layer 151, a second insulating layer 153, a second mask layer 155, and a third insulating layer 157. In some embodiments, to cover the first insulating layer P141, the first mask layer 151, the second insulating layer 153, the second mask layer 155 and the third insulating layer 157 may be sequentially stacked and formed. The first mask layer 151, the second insulating layer 153, the second mask layer 155, and the third insulating layer 157 may be formed through a CVD process and a process of the like.

In some embodiments, the second insulating layer 153 and the third insulating layer 157 may each include oxide, nitride, and/or a combination thereof. For example, the second insulating layer 153 and the third insulating layer 157 may each include silicon nitride, silicon oxide, silicon oxynitride, and/or a combination thereof.

In some embodiments, the first mask layer 151 may be an amorphous carbon layer including amorphous carbon, and the second mask layer 155 may include carbon. For example, the second mask layer 155 may be a carbon-based spin-on-hardmask (SOH) layer, but example embodiments are not limited thereto.

Referring to FIGS. 7A, 7B, and 7C, a plurality of first space insulating patterns 156 may be formed on the second insulating layer 153 to be apart from each other in the first horizontal direction (e.g. X direction) and extending in the second horizontal direction (e.g. Y direction).

In detail, a plurality of first photoresist patterns (not shown) are formed on the third insulating layer 157, and a portion of the third insulating layer 157 and a portion of the second mask layer 155 are etched and removed using the first photoresist pattern as an etch mask. In this state, the first photoresist patterns are arranged to be spaced apart from each other in the first horizontal direction (e.g. X direction) and may each have a bar shape extending in the second horizontal direction (e.g. Y direction). The first photoresist patterns may have a line-and-space shape.

In this state, the upper surface of the second insulating layer 153 that overlaps the removed portion of the third insulating layer 157 and the removed portion of the second mask layer 155 in the vertical direction (e.g. Z direction) may be exposed. Furthermore, the first photoresist patterns may be transferred to the third insulating layer 157 and the second mask layer 155 by the etching process.

Then, a space insulating layer may be formed, which fills a space between the portions of the third insulating layer 157 and the second mask layer 155 removed in the process described above and conformally covers the exposed upper surface of the second insulating layer 153. Then, a horizontal portion of a space insulating layer covering the upper surface of the second insulating layer 153 and the upper surface of the third insulating layer 157 may be removed. As the horizontal portion of the space insulating layer is removed, a third mask layer 158 that fills the exposed space may be formed. In this state, the third mask layer 158 may be a carbon-based SOH layer, but example embodiments are not limited thereto.

Then, the first space insulating patterns 156 may be formed by etching the third insulating layer 157, the second mask layer 155, the third mask layer 158, and the space insulating layer. The first space insulating patterns 156 may each include, for example, oxide such as silicon oxide. In this state, the first space insulating patterns 156 may be arranged to be spaced apart from each other in the first horizontal direction (e.g. X direction) and have a bar shape extending in the second horizontal direction (e.g. Y direction). The first space insulating patterns 156 may have a line-and-space shape. The first space insulating patterns 156 may have a narrower pitch than that of the first photoresist pattern.

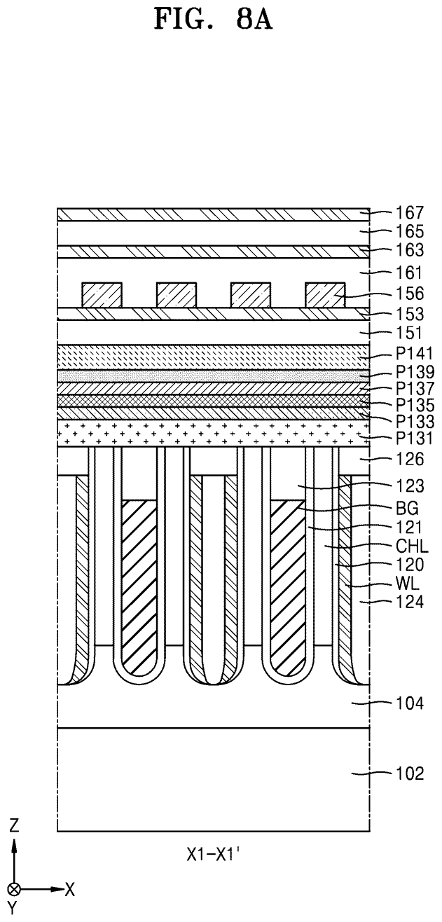

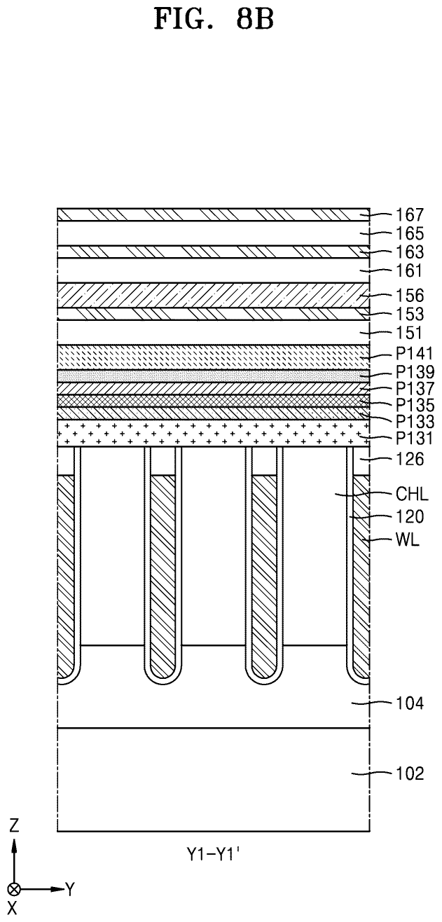

Referring to FIGS. 8A and 8B, in the result of FIGS. 7A and 7B, the second mask layer 155 and the third mask layer 158 filling between the first space insulating patterns 156 are removed to expose the first space insulating patterns 156.

Then, a second mask structure may be formed on the first space insulating patterns 156. The second mask structure may include a fourth mask layer 161, a fourth insulating layer 163, a fifth mask layer 165, and a fifth insulating layer 167. The fourth mask layer 161 may be formed to cover the first space insulating patterns 156 that is exposed. Then, the fourth insulating layer 163, the fifth mask layer 165, and the fifth insulating layer 167 may be sequentially stacked and formed on the fourth mask layer 161. The fourth mask layer 161, the fourth insulating layer 163, the fifth mask layer 165, and the fifth insulating layer 167 may be formed through a CVD process and a process of the like.

In some embodiments, the fourth insulating layer 163 and the fifth insulating layer 167 may each include oxide, nitride, and/or a combination thereof. For example, the fourth insulating layer 163 and the fifth insulating layer 167 may each include silicon nitride, silicon oxide, silicon oxynitride, and/or a combination thereof.

In some embodiments, the fourth mask layer 161 and the fifth mask layer 165 may each include carbon. For example, the fourth mask layer 161 and the fifth mask layer 165 may each be a carbon-based SOH layer, but example embodiments are not limited thereto.

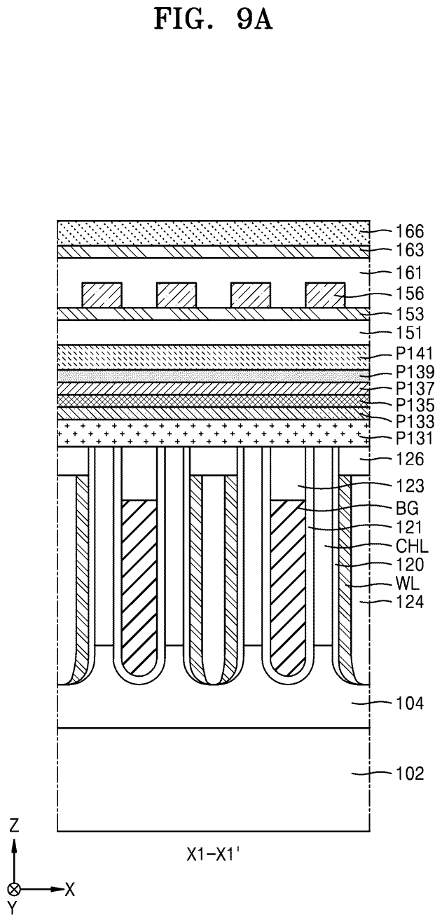

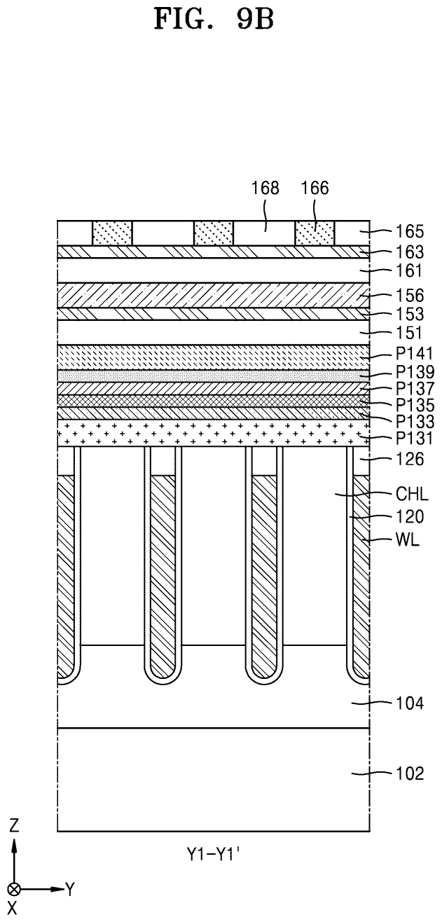

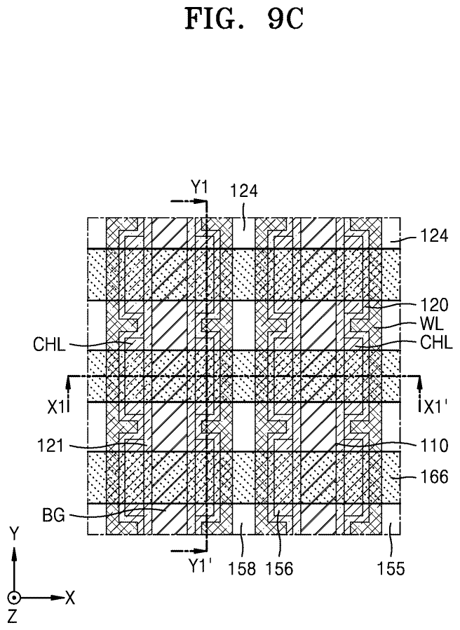

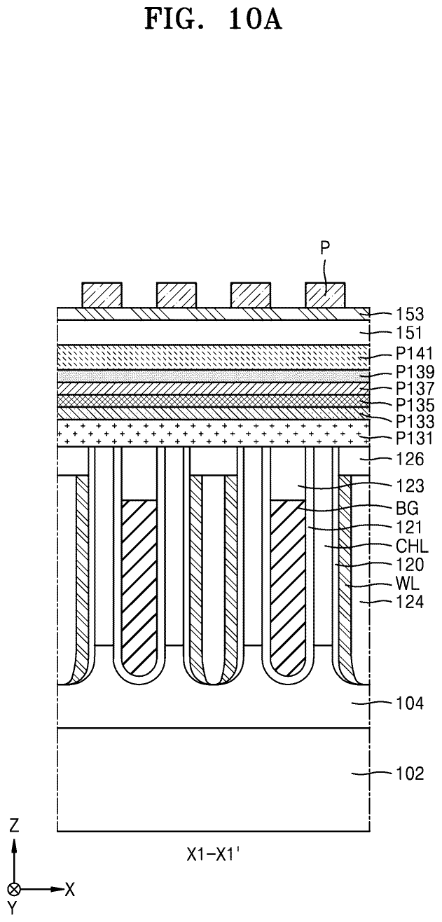

Referring to FIGS. 9A, 9B, and 9C, a plurality of second space insulating patterns 166 may be formed and arranged on the fourth insulating layer 163 to be spaced apart from each other in the second horizontal direction (e.g. Y direction) and extending in the first horizontal direction (e.g. X direction).

A plurality of second photoresist patterns (not shown), and a portion of the fifth insulating layer 167 and a portion of the fifth mask layer 165 may be etched and removed using the second photoresist patterns as an etch mask. In this state, the second photoresist patterns are arranged to be spaced apart from each other in the second horizontal direction (e.g. Y direction) and have a bar shape extending in the first horizontal direction (e.g. X direction). The second photoresist patterns may have a line-and-space shape.

In this state, an upper surface of the fourth insulating layer 163 overlapping the removed portions of the fifth insulating layer 167 and the fifth mask layer 165 in the vertical direction may be exposed. Furthermore, the second photoresist patterns may be transferred to the fifth insulating layer 167 and the fifth mask layer 165 through the etching process.

Then, a space insulating layer may be formed, which fills a space between the portions of the fifth insulating layer 167 and the fifth mask layer 165 removed in the process described above and conformally covers the exposed upper surface of the fourth insulating layer 163. Then, the horizontal portion of the space insulating layer covering the upper surface of the fourth insulating layer 163 and an upper surface of the fifth insulating layer 167 may be removed. A sixth mask layer 168 may be formed, which fills a space that is exposed as the horizontal portion of the space insulating layer is removed. In this state, the sixth mask layer 168 may be a carbon-based SOH layer, but example embodiments are not limited thereto.

Then, the second space insulating patterns 166 may be formed by etching the fifth insulating layer 167, the fifth mask layer 165, the sixth mask layer 168, and the space insulating layer. The second space insulating patterns 166 may each include, for example, oxide such as silicon oxide. In this state, the second space insulating patterns 166 are arranged to be spaced apart in the second horizontal direction (e.g. Y direction) and have a bar shape extending in the first horizontal direction (e.g. X direction). The second space insulating patterns 166 may have a line-and-space shape. The second space insulating patterns 166 may each have a pitch narrower than the second photoresist patterns.

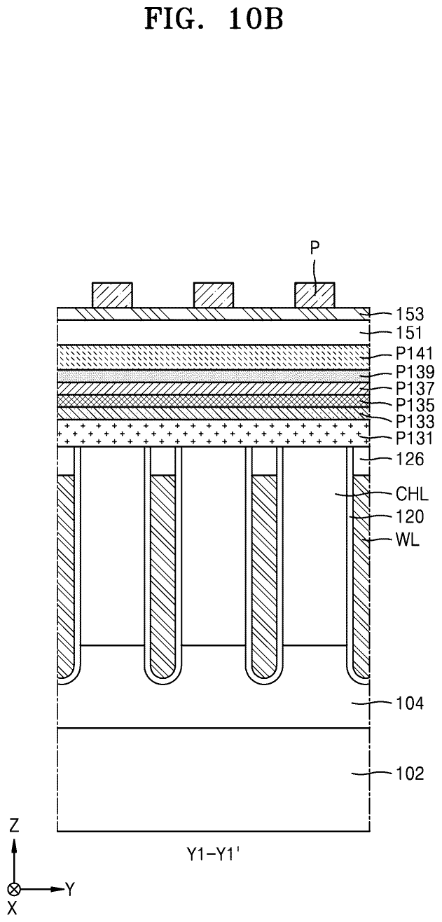

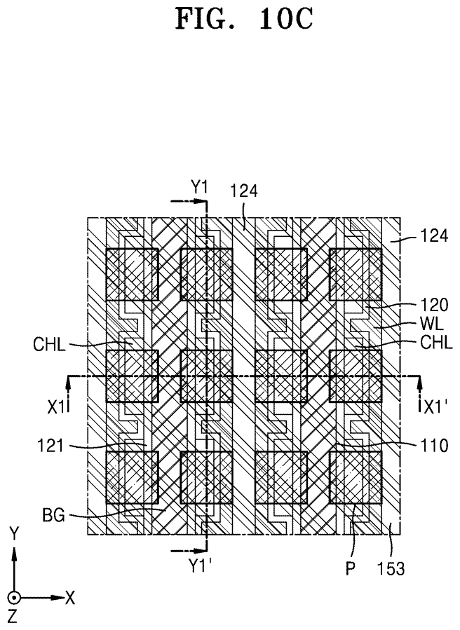

Referring to FIGS. 10A, 10B, and 10C, a plurality of first insulating patterns P may be formed on the second insulating layer 153. The plurality of first insulating patterns P may be formed on the second insulating layer 153 to be spaced apart from each other in the first horizontal direction (e.g. X direction) and the second horizontal direction (e.g. Y direction).

In some embodiments, a portion of the fourth insulating layer 163 and a portion of the fourth mask layer 161 may be etched and removed using the second space insulating patterns 166 as an etch mask. The second space insulating patterns 166 may be transferred to the fourth insulating layer 163 and the fourth mask layer 161 through the etching process.

Then, the plurality of first insulating patterns P may be formed by etching and removing a portion of the first space insulating patterns 156 using the pattern transferred to the fourth insulating layer 163 and the fourth mask layer 161. In this state, the plurality of first insulating patterns P may be formed at positions overlapping the plurality of channel regions CHLs in the vertical direction (e.g. Z direction).

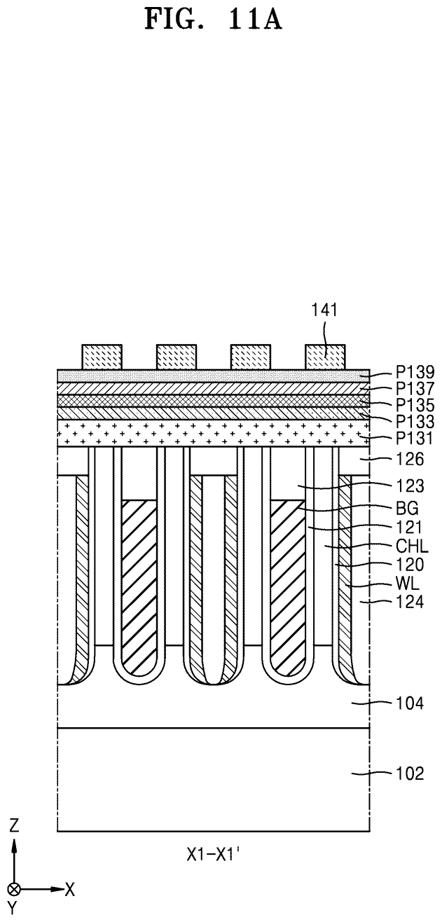

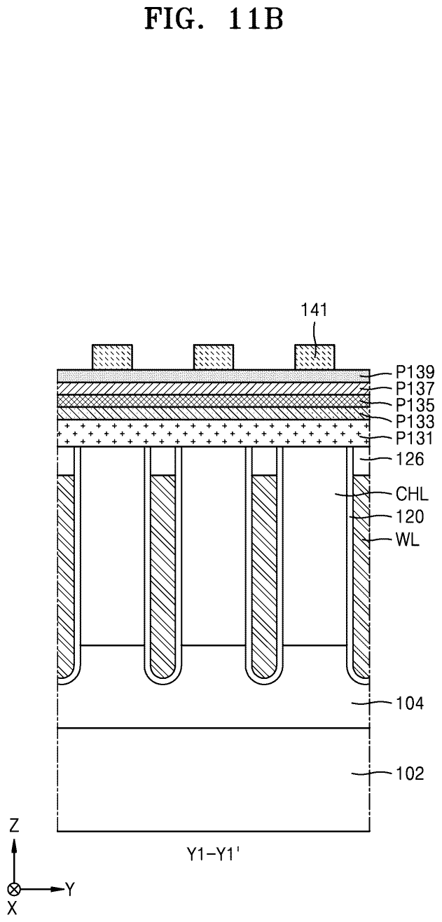

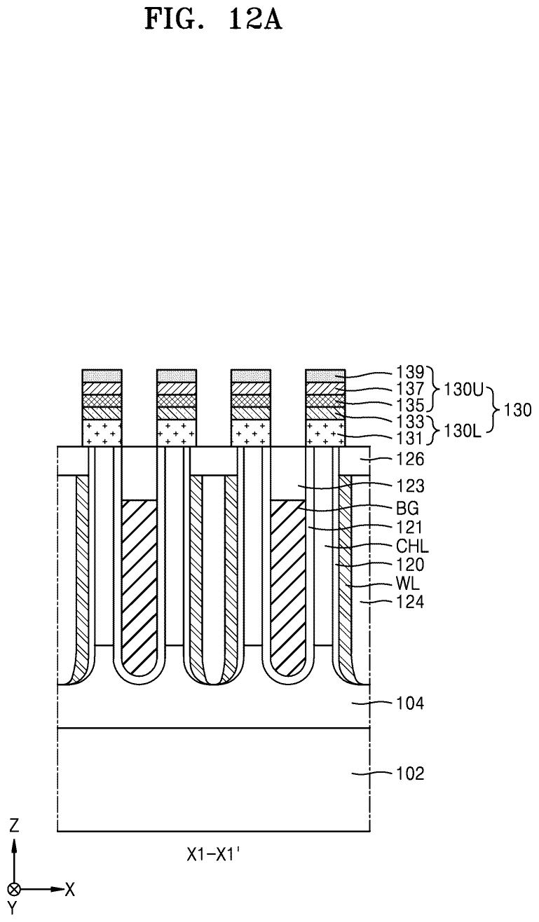

Referring to FIGS. 11A and 11B, a plurality of second insulating patterns 141 may be formed on the third upper conductive layer P139. In the result of FIGS. 10A and 10B, a portion of the second insulating layer 153 and a portion of the first mask layer 151 may be etched and removed using the first insulating patterns P as an etch mask. The first insulating patterns P may be transferred to the second insulating layer 153 and the first mask layer 151 through the etching process.

Then, the plurality of second insulating patterns 141 may be formed by etching and removing a portion of the first insulating layer P141 using the pattern transferred to the second insulating layer 153 and the first mask layer 151. As a result, the first insulating patterns P may be transferred to the plurality of second insulating patterns 141. Accordingly, the plurality of second insulating patterns 141 may be formed at positions overlapping the channel regions CHLs in the vertical direction (e.g. Z direction). Furthermore, the plurality of second insulating patterns 141 may be arranged on the conductive layer structure to be apart from each other in the first horizontal direction (e.g. X direction) and the second horizontal direction (e.g. Y direction).

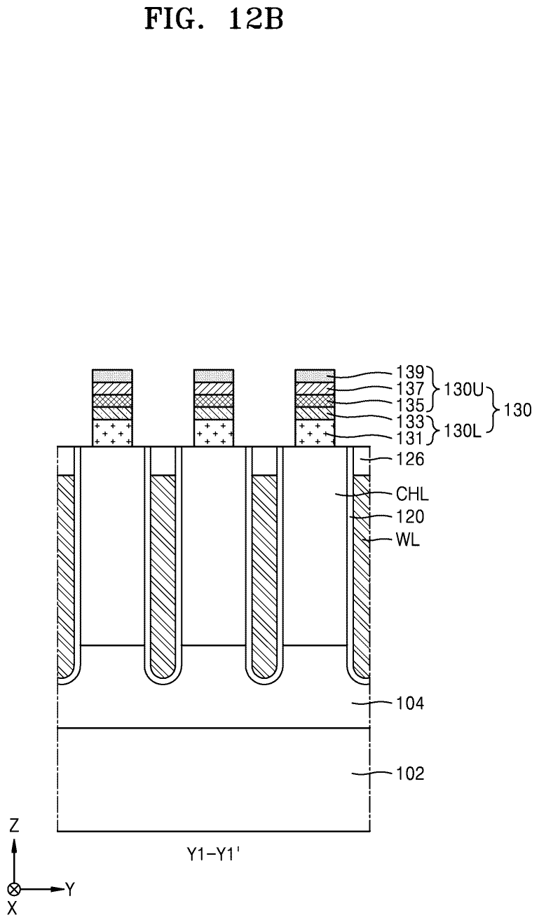

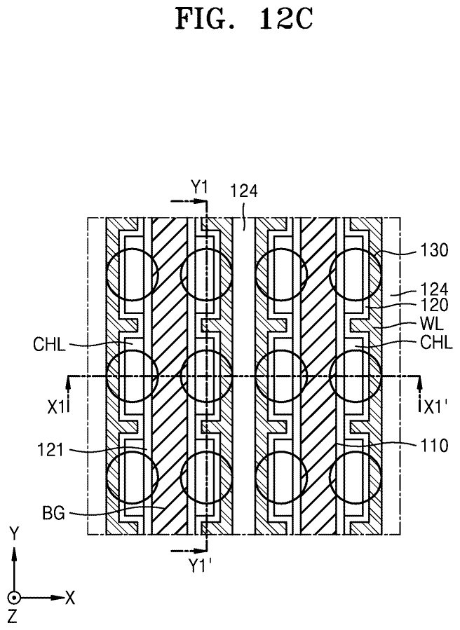

Referring to FIGS. 12A, 12B, and 12C, a portion of the first lower conductive layer P131, a portion of the second lower conductive layer P133, a portion of the first upper conductive layer P135, a portion of the second upper conductive layer P137, and a portion of the third upper conductive layer P139 may be etched and removed using the plurality of second insulating patterns 141 as an etch mask. The plurality of contact plugs 130 may be formed on the plurality of channel regions CHLs using the plurality of second insulating patterns 141 as an etch mask.

In some embodiments, the plurality of contact plugs 130 may include the upper contact plug 130U and the lower contact plug 130L, and the upper contact plug 130U and the lower contact plug 130L may be formed in an integrated structure using the plurality of second insulating patterns 141 as an etch mask. As used herein, an “integrated structure” may refer to a laminate or other multi-layer structure with respective sublayers stacked directly on one another.

In some embodiments, the lower contact plug 130L may include the first lower conductive pattern 131 and the second lower conductive pattern 133, and the upper contact plug 130U may include the first upper conductive pattern 135, the second upper conductive pattern 137, and the third upper conductive pattern 139. In the method of manufacturing the semiconductor memory device 100 according to an aspect of the inventive concept, the first lower conductive pattern 131, the second lower conductive pattern 133, the first upper conductive pattern 135, the second upper conductive pattern 137, and the third upper conductive pattern 139 may be formed in an integrated structure. The first lower conductive pattern 131, the second lower conductive pattern 133, the first upper conductive pattern 135, the second upper conductive pattern 137, and the third upper conductive pattern 139 may be formed using the plurality of second insulating patterns 141 as an etch mask through one etching process.

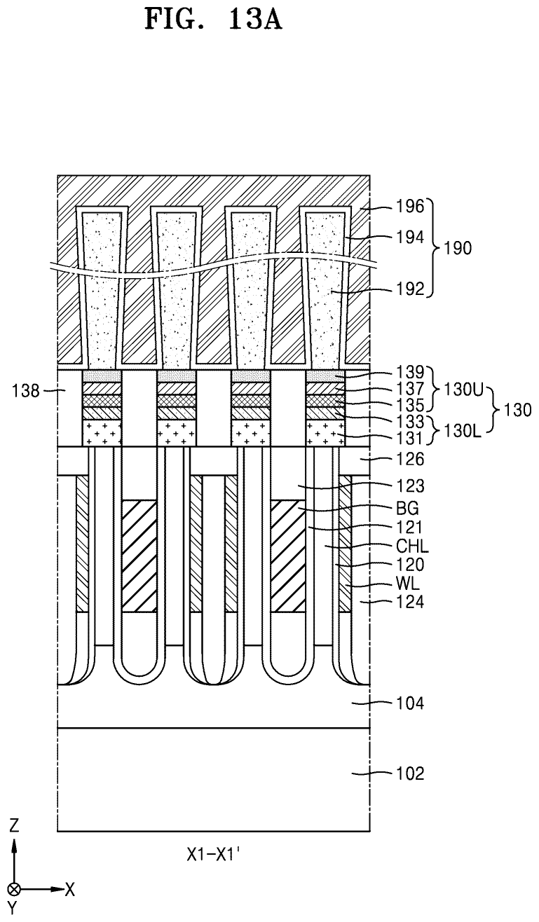

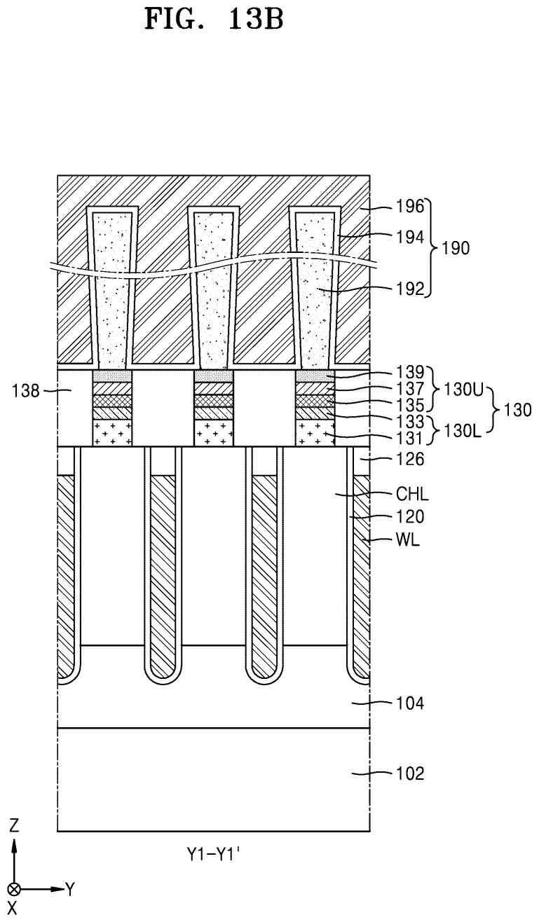

Referring to FIGS. 13A and 13B, the interlayer insulating film 138 may be formed, which fills a space between the plurality of contact plugs 130. As the interlayer insulating film 138 filling a space between the plurality of contact plugs 130 is formed, the plurality of contact plugs 130 may be separated from each other. Then, the capacitor structure 190 connected to the plurality of contact plugs 130 may be formed on the plurality of contact plugs 130 and the interlayer insulating film 138. In the method of manufacturing the semiconductor memory device 100 according to an aspect of the inventive concept, a conductive layer structure in the form of a flat plate may be formed, and the conductive layer structure may be etched by a relief method, thereby forming the plurality of contact plugs 130.

In a semiconductor memory device according to a comparative example, in a process of forming a landing pad corresponding to the upper contact plug 130U, seams and/or voids may be formed inside the landing pad such performance of the semiconductor memory device deteriorates. Furthermore, there is a problem affecting the critical dimension of the landing pad due to a process of replacing the landing pad.

In the method of manufacturing the semiconductor memory device 100 according to an aspect of the inventive concept, as the upper contact plug 130U and the lower contact plug 130L are formed in an integrated structure through one etching process, the deterioration of the plurality of contact plugs 130 occurring in the process of forming the plurality of contact plugs 130 may be prevented. As the upper contact plug 130U is formed in an integrated structure with the lower contact plug 130L, by omitting a landing pad replacement process, a factor affecting the threshold dimension of the upper contact plug 130U may be reduced so that the semiconductor memory device 100 having a structure with improved reliability may be provided. Furthermore, as a conductive layer structure may be formed in a flat plate structure, and the conductive layer structure may be etched by a relief method to form the plurality of contact plugs 130, forming seams and/or voids in the plurality of contact plugs 130 may be prevented so that the performance of the semiconductor memory device 100 may be improved.

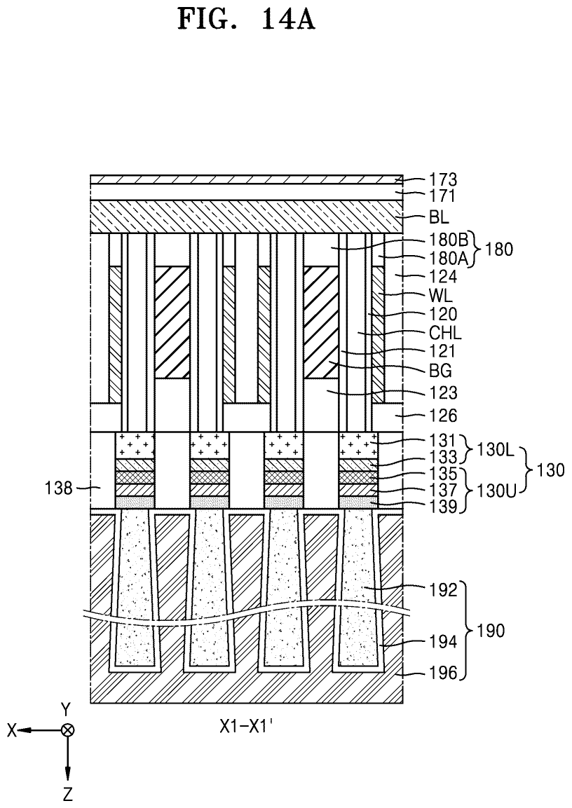

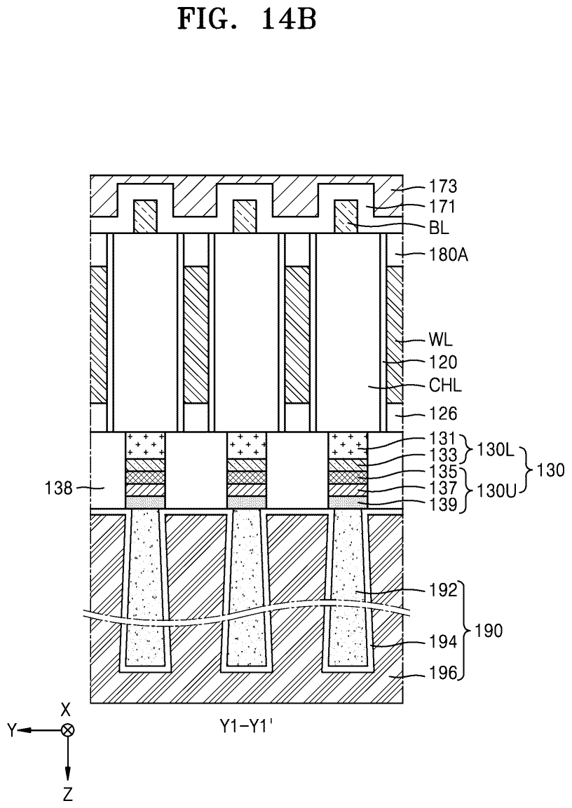

Referring to FIGS. 14A and 14B, by flipping the result of FIGS. 13A and 13B such that the directions of the upper and lower portions in the vertical direction (e.g. Z direction) are inverted, the substrate 102 faces upwards in the vertical direction (e.g. Z direction), a grinding process and a wet etching process of the substrate 102 may be sequentially performed from the back surface of the substrate 102 that is exposed until the embedded insulating layer 104 and the plurality of channel regions CHLs are exposed.

Then, a plurality of spaces are provided by removing a portion of each of the plurality of back gate electrodes BGs and the plurality of word lines WLs, which are exposed, and a plurality of the second embedded insulating patterns 180A and a plurality of the second capping insulating patterns 180B may be formed, which fill the spaces. The second embedded insulating patterns 180A and the second capping insulating patterns 180B may constitute the embedded structure 180.

Then, the plurality of conductive lines BLs covering the embedded structure 180 and the plurality of channel regions CHLs may be formed. Furthermore, by sequentially forming the conductive line insulating layer 171 and the shield metal layer 173 on the plurality of conductive lines BLs, the semiconductor memory device 100 illustrated in FIGS. 1, 2A, and 2B may be manufactured.

While aspects of the inventive concept have been particularly shown and described with reference to example embodiments thereof, it will be understood by one of ordinary skill in the art that various changes in form and detail may be made therein without departing from the scope of the following claims.

What is claimed is:

1. A method of manufacturing a semiconductor memory device, the method comprising:
providing a substrate structure comprising a substrate, an embedded insulating layer, and an active layer, sequentially stacked;
forming, by etching portions of the substrate structure, a channel region and a plurality of word lines, wherein the channel region and the plurality of word lines are spaced apart from each other in a first direction and extend in a second direction that intersects the first direction;
forming a conductive layer structure on the channel region;
forming a first mask structure on the conductive layer structure;
forming a plurality of first space insulating patterns by etching portions of the first mask structure;
forming a second mask structure on the plurality of first space insulating patterns;
forming a plurality of second space insulating patterns by etching portions of the second mask structure;
forming a plurality of first insulating patterns by removing portions of the plurality of first space insulating patterns using the plurality of second space insulating patterns as a first etch mask; and
forming a plurality of contact plugs by etching portions of the conductive layer structure using the plurality of first insulating patterns as a second etch mask.

2. The method of claim 1, wherein each of the plurality of contact plugs comprises an upper contact plug and a lower contact plug,
wherein forming the plurality of contact plugs comprises forming the upper contact plug and the lower contact plug in an integrated structure.

3. The method of claim 2, wherein the upper contact plug comprises a first upper conductive pattern, a second upper conductive pattern, and a third upper conductive pattern,
the lower contact plug comprises a first lower conductive pattern and a second lower conductive pattern, and
forming the plurality of contact plugs comprises forming the first upper conductive pattern, the second upper conductive pattern, the third upper conductive pattern, the first lower conductive pattern, and the second lower conductive pattern, in the integrated structure.

4. The method of claim 2, wherein the conductive layer structure comprises a first lower conductive layer, a second lower conductive layer, a first upper conductive layer, a second upper conductive layer, and a third upper conductive layer, sequentially stacked,
wherein the first lower conductive layer, the second lower conductive layer, the first upper conductive layer, the second upper conductive layer, and the third upper conductive layer are stacked in a flat plate form.

5. The method of claim 1, wherein the forming of the plurality of first insulating patterns comprises forming the plurality of first insulating patterns at positions overlapping the channel region in a third direction that is perpendicular to the first direction and the second direction.

6. The method of claim 1, wherein respective ones of the plurality of first space insulating patterns are spaced apart from each other in the first direction and extend in the second direction, and
respective ones of the plurality of second space insulating patterns are spaced apart from each other in the second direction and extend in the first direction.

7. The method of claim 6, wherein the forming of the plurality of first insulating patterns comprises forming the plurality of first insulating patterns spaced apart from each other in the first direction and the second direction.

8. The method of claim 1, further comprising:
forming an interlayer insulating film between the plurality of contact plugs; and
forming a capacitor structure on the plurality of contact plugs and the interlayer insulating film.

9. The method of claim 8, further comprising:
exposing the channel region by removing a portion of a surface of the substrate that is opposite the capacitor structure; and
forming a conductive line on the exposed channel region that extends in the first direction.

10. The method of claim 1, further comprising forming, by etching portions of the substrate structure, a plurality of back gate electrodes that is spaced apart from each other in the first direction and extend in the second direction.

11. A method of manufacturing a semiconductor memory device, the method comprising:
providing a substrate structure comprising a substrate, an embedded insulating layer, and an active layer, sequentially stacked;
forming, by etching portions of the substrate structure, a channel region and a plurality of word lines spaced apart from each other in a first direction and extending in a second direction that intersects the first direction;
forming a conductive layer structure and an insulating layer that are sequentially on the channel region;
forming a first mask structure on the insulating layer;
forming, by etching portions of the first mask structure, a plurality of first space insulating patterns that extend in the second direction;
forming a second mask structure on the plurality of first space insulating patterns;
forming, by etching portions of the second mask structure, a plurality of second space insulating patterns that extend in the first direction;
forming a plurality of first insulating patterns by removing portions of the plurality of first space insulating patterns using the plurality of second space insulating patterns as a first etch mask
forming a plurality of second insulating patterns on the conductive layer structure by patterning the insulating layer using the plurality of first insulating patterns as a second etch mask; and
forming a plurality of contact plugs in an integrated structure comprising an upper contact plug and a lower contact plug, by etching portions of the conductive layer structure using the plurality of second insulating patterns as a third etch mask.

12. The method of claim 11, wherein the upper contact plug comprises a first upper conductive pattern, a second upper conductive pattern, and a third upper conductive pattern,
the lower contact plug comprises a first lower conductive pattern and a second lower conductive pattern, and
the forming of the plurality of contact plugs comprises forming the first upper conductive pattern, the second upper conductive pattern, the third upper conductive pattern, the first lower conductive pattern, and the second lower conductive pattern, in the integrated structure.

13. The method of claim 11, wherein the conductive layer structure comprises a first lower conductive layer, a second lower conductive layer, a first upper conductive layer, a second upper conductive layer, and a third upper conductive layer, sequentially stacked, and
the first lower conductive layer, the second lower conductive layer, the first upper conductive layer, the second upper conductive layer, and the third upper conductive layer are stacked in a flat plate form.

14. The method of claim 11, wherein the forming of the plurality of second insulating patterns comprises forming the plurality of second insulating patterns at positions overlapping the channel region in a third direction that is perpendicular to the first direction and the second direction.

15. The method of claim 11, wherein the forming of the plurality of second insulating patterns comprises forming the plurality of second insulating patterns spaced apart from each other in the first direction and the second direction.

16. The method of claim 11, further comprising:
forming an interlayer insulating film between the plurality of contact plugs; and
forming a capacitor structure on the plurality of contact plugs and the interlayer insulating film.

17. A semiconductor memory device comprising:
a plurality of conductive lines extending in a first direction;
a plurality of channel regions electrically connected to the plurality of conductive lines;
a pair of word lines between a first channel region and an adjacent second channel region of the plurality of channel regions, spaced apart from each other in the first direction, and extending in a second direction that intersects the first direction; and
a plurality of contact plugs spaced apart from the plurality of conductive lines with the plurality of channel regions therebetween in a third direction that is perpendicular to the first and second directions, wherein each of the plurality of contact plugs comprises a lower contact plug in contact with a channel region of the plurality of channel regions and an upper contact plug in contact with an upper surface of the lower contact plug,
wherein the lower contact plug and the upper contact plug are an integrated structure.

18. The semiconductor memory device of claim 17, wherein a side surface of the lower contact plug is coplanar with a side surface of the upper contact plug.

19. The semiconductor memory device of claim 17, further comprising a plurality of back gate electrodes that are spaced apart from each other in the first direction and extend in the second direction between the first or second channel region and an adjacent third channel region of the plurality of channel regions.

20. The semiconductor memory device of claim 17, further comprising a capacitor structure in contact with an upper surface of the upper contact plug.
